(19) United States
(12) Patent Application Publication
(10) Pub. No.: US 2022/0173494 A1
(43) Pub. Date: Jun. 2, 2022

(54) ANTENNA ARRAY FOR 5G COMMUNICATIONS, ANTENNA STRUCTURE, NOISE-SUPPRESSING THERMALLY CONDUCTIVE SHEET, AND THERMALLY CONDUCTIVE SHEET

(71) Applicant: Dexerials Corporation, Shimotsuke-shi, Tochigi (JP)

(72) Inventors: Sergey BOLOTOV, Shimotsuke-shi, Tochigi (JP); Hiroyuki RYOSON, Shimotsuke-shi, Tochigi (JP); Keisuke ARAMAKI, Shimotsuke-shi, Tochigi (JP); Yusuke KUBO, Shimotsuke-shi, Tochigi (JP)

(73) Assignee: Dexerials Corporation, Shimotsuke-shi, Tochigi (JP)

(21) Appl. No.: 17/593,631

(22) PCT Filed: Feb. 27, 2020
(86) PCT No.: PCT/JP2020/008178

§ 371 Date: Sep. 22, 2021

(30) Foreign Application Priority Data
Mar. 29, 2019 (JP) 2019-067104
Feb. 26, 2020 (JP) 2020-030821

(51) Int. Cl. H01Q 1/22; H01Q 1/42; H01Q 17/00; H01Q 3/34; H01Q 9/04

(52) U.S. Cl. CPC H01Q 1/2283; H01Q 1/422; H04B 7/0413; H01Q 3/34; H01Q 9/0407; H01Q 17/004

(57) ABSTRACT

The disclosure aims at providing an antenna array for 5G communications that has superior thermal dissipation and crosstalk suppression effect. To achieve the above-described object, an antenna array 1 for 5G communications according to the disclosure includes a substrate 10; at least one high-frequency semiconductor device 20, a noise-suppressing thermally conductive sheet 20, and a first thermal dissipation member 41 sequentially formed on one surface 10a of the substrate 10; and at least one antenna 50 and a second thermal dissipation member 42 sequentially formed on the other surface 10b of the substrate 10.

### TECHNICAL FIELD

The present disclosure relates to an antenna array for 5G communications and an antenna structure having superior thermal dissipation and crosstalk suppression effect, and a noise-suppressing thermally conductive sheet and a thermally conductive sheet suitable for use in the antenna array for 5G communications and the antenna structure.

### BACKGROUND

In preparation for 5G the next generation high-speed and high-capacity communications, various communication technologies are being developed to support ultra-high-speed and high-capacity communications. “Massive MIMO” is known as one of the technologies. Massive MIMO is an elemental technology employing “massive-element antenna” in which a large number i.e. tens or a hundred or more of antennas are assumed to be mounted on a base station side.

By increasing the number of antenna elements horizontally and vertically, as in a Massive MIMO structure, a beam for propagating communication tends to be thinner. The thinner and longer beam, which is controlled so as to draw a straight line like a laser light as an image, enables delivery of highly directional radio waves with pinpoint accuracy toward a specific communication device such as a smartphone. Therefore, it is expected that adoption of Massive MIMO will result in effects on higher capacity communication and utilization efficiency than ever before.

In an antenna array (an aggregation of antenna structures) such as Massive MIMO described above, high-frequency semiconductor devices (hereinafter also referred to as “RFICs”) used therein generate a lot of heat, so a thermal dissipation member such as a heat sink is commonly used to dissipate the heat to the outside.

However, in the antenna array in which the many RFICs are mounted in a single device, the amount of heat generation is large, and the conventional technology may not be able to provide sufficient thermal dissipation.

In a case in which a plurality of antennas and RFICs are aligned like in the antenna array, there is a problem of the occurrence of crosstalk between the RFICs. Increase in the crosstalk causes communication inhibition and miscommunication, and it has therefore been desired to develop a technology that can effectively suppress the crosstalk, in addition to providing the thermal dissipation described above.

For example, Patent Literature (PTL) 1 discloses a Massive MIMO system that includes a rectangular dielectric; input/output electrodes and a conductor film formed on an outer periphery of the dielectric, the input/output electrodes extending from a first end, which is near the apex of the dielectric, to the inward of a bottom surface of the dielectric; and a dielectric waveguide filter having a conductor-free portion, for the purpose of suppressing losses due to reflection and radiation of an electromagnetic field in an input/output portion of a dielectric waveguide.

However, although the technology disclosed in PTL 1 provides a certain level of noise-suppressing effect in the input/output portion of the dielectric waveguide, the thermal dissipation is not sufficient, and there is a problem of heat generation after prolonged use. Furthermore, further improvement in the crosstalk suppression effect in the case of increasing the number of antennas is desired.

### CITATION LIST

### Patent Literatures

PTL 1: JP 2012-204632A

### SUMMARY

### Technical Problem

It would be helpful to provide an antenna array for 5G communications and an antenna structure having superior thermal dissipation and crosstalk suppression effect. It would be also helpful to provide a noise-suppressing thermally conductive sheet and a thermally conductive sheet suitable for use in the antenna array for 5G communications and the antenna structure having superior thermal dissipation and crosstalk suppression effect.

### Solution to Problem

The inventors have studied to solve the above problem and found that by providing a noise-suppressing thermally conductive sheet on high-frequency semiconductor devices (RFIC) formed on one surface of a substrate, it is possible to obtain high electromagnetic wave suppression effect to suppress crosstalk generated between the RFICs. Furthermore, since the noise-suppressing thermally conductive sheet is provided between each of the high-frequency semiconductor devices and a thermal dissipation member, it is possible to efficiently transfer heat generated by the high-frequency semiconductor devices to the thermal dissipation member (first thermal dissipation member), and heat generated by antennas can also be diffused by a thermal dissipation member (second thermal dissipation member), thus improving thermal dissipation.

The present disclosure is based on the above findings and is summarized as follows.

(1) An antenna array for 5G communications including:

a substrate;

at least one high-frequency semiconductor device, a noise-suppressing thermally conductive sheet, and a first thermal dissipation member sequentially formed on one surface of the substrate; and

at least one antenna and a second thermal dissipation member sequentially formed on the other surface of the substrate.

According to the above configuration, it is possible to achieve superior thermal dissipation and crosstalk suppression effect.

(2) The antenna array for 5G communications described in the above (1), further including a thermally conductive sheet disposed between the at least one antenna and the second thermal dissipation member.
(3) The antenna array for 5G communications described in the above (1) or (2), wherein the noise-suppressing thermally conductive sheet contains magnetic powder.
(4) The antenna array for 5G communications described in any one of the above (1) to (3), wherein the noise-suppressing thermally conductive sheet contains carbon fiber.
(5) The antenna array for 5G communications described in any one of the above (1) to (4), wherein the noise-suppressing thermally conductive sheet has a dielectric constant of 20 or more.
(6) The antenna array for 5G communications described in any one of the above (1) to (5), wherein the noise-suppressing thermally conductive sheet has a magnetic permeability of more than 1.
(7) The antenna array for 5G communications described in any one of the above (1) to (6), wherein the noise-suppressing thermally conductive sheet has a thermal resistance of 300 Kmm²/W or less.
(8) The antenna array for 5G communications described in any one of the above (1) to (7), wherein the antenna array for 5G communications is used as Massive MIMO.
(9) An antenna structure including:

a substrate;

a high-frequency semiconductor device, a noise-suppressing thermally conductive sheet, and a first thermal dissipation member sequentially formed on one surface of the substrate; and

an antenna and a second thermal dissipation member sequentially formed on the other surface of the substrate.

According to the above configuration, it is possible to achieve superior thermal dissipation and crosstalk suppression effect.

(10) A noise-suppressing thermally conductive sheet used in an antenna array for 5G communications, wherein

the noise-suppressing thermally conductive sheet is disposed between at least one high-frequency semiconductor device formed on a substrate and a thermal dissipation member.

According to the above configuration, it is possible to obtain a noise-suppressing thermally conductive sheet suitable for a semiconductor device having superior thermal dissipation and crosstalk suppression effect.

(11) A thermally conductive sheet used in an antenna array for 5G communications, wherein

the thermally conductive sheet is disposed between at least one antenna formed on a substrate and a thermal dissipation member.

According to the above configuration, it is possible to obtain a thermally conductive sheet suitable for a semiconductor device having superior thermal dissipation and crosstalk suppression effect.

### Advantageous Effect

According to the present disclosure, it is possible to provide an antenna array for 5G communications and an antenna structure having superior thermal dissipation and crosstalk suppression effect. The present disclosure also makes it possible to provide a noise-suppressing thermally conductive sheet and a thermally conductive sheet suitable for use in the antenna array for 5G communications and the antenna structure having superior thermal dissipation and crosstalk suppression effect.

### BRIEF DESCRIPTION OF THE DRAWINGS

In the accompanying drawings:

FIG. 1 is a schematic diagram in cross section illustrating an embodiment of an antenna array for 5G communications according to the present disclosure;

FIG. 2 is a schematic diagram in cross section illustrating another embodiment of the antenna array for 5G communications according to the present disclosure;

FIG. 3 is a graph illustrating the amount of near-end crosstalk (S31) in the case of changing the conditions of a noise-suppressing thermally conductive sheet of the antenna array for 5G communications in Example 1;

FIGS. 4A to 4D are graphs illustrating the amounts of near-end crosstalk (S31) in the case of changing the dielectric constant of a noise-suppressing thermally conductive sheet of the antenna array for 5G communications in Example 3, and FIG. 4A illustrates the amount of near-end crosstalk at 10 GHz, FIG. 4B illustrates the amount of near-end crosstalk at 20 GHz, FIG. 4C illustrates the amount of near-end crosstalk at 40 GHz, and FIG. 4D illustrates the amount of near-end crosstalk at 60 GHz; and

FIG. 5 is a graph illustrating the amount of near-end crosstalk (S31) at 28 GHz in the case of changing the magnetic permeability of a noise-suppressing thermally conductive sheet of the antenna array for 5G communications in Example 4.

### DETAILED DESCRIPTION

Embodiments of the present disclosure will be described below in detail using the drawings.

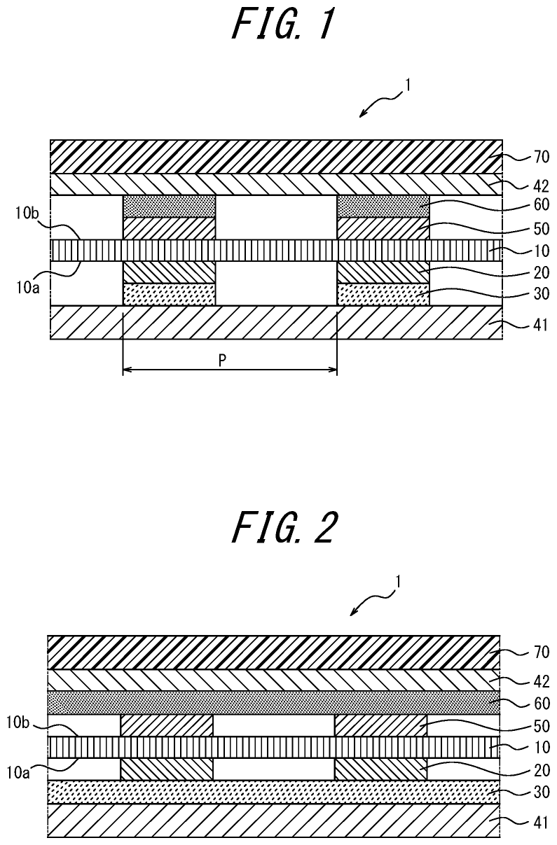

Here, FIGS. 1 and 2 each schematically illustrate an embodiment of a cross-section of an antenna array for 5G communications according to the present disclosure. For convenience of explanation, in each drawing, the shape and scale of each component are illustrated differently from the actual ones. The shape and scale of each component may be changed as appropriate for each semiconductor device, except as specified herein.

### Antenna Array for 5G Communications

As illustrated in FIG. 1, an antenna array 1 for 5G communications according to an embodiment of the present disclosure includes:

a substrate 10;

at least one high-frequency semiconductor device 20, a noise-suppressing thermally conductive sheet 30, and a first thermal dissipation member 41 sequentially formed on one surface 10a of the substrate 10; and

at least one antenna 50, a second thermal dissipation member 42 sequentially formed on the other surface 10b of the substrate 10.

In the antenna array 1 for 5G communications according to the embodiment of the present disclosure, since the noise-suppressing thermally conductive sheet 30 is provided, it is possible to absorb and/or block electromagnetic waves being noise generated by the high-frequency semiconductor devices 20, thus suppressing increase in crosstalk without interfering with transmission and reception of radio waves. In addition, in the antenna array 1 for 5G communications according to the embodiment of the present disclosure, since the noise-suppressing thermally conductive sheet 30 is provided between each of the high-frequency semiconductor devices 20 and the first thermal dissipation member 41, heat generated by the high-frequency semiconductor devices 20 can be efficiently transferred to the first thermal dissipation member 41, thus achieving superior thermal dissipation.

Furthermore, in the antenna array 1 for 5G communications according to the embodiment of the present disclosure, the second thermal dissipation member 42 formed on the other surface 10b of the substrate 10 can efficiently dissipate heat generated by the antennas, so it is possible to further improve thermal dissipation of the antenna array 1 for 5G communications as a whole.

On the other hand, in an antenna array for 5G communications according to conventional technology, no noise-suppressing thermally conductive sheet 30 is provided in contact with the high-frequency semiconductor devices 20, unlike the present disclosure, and therefore a sufficient crosstalk suppression effect cannot be obtained. Furthermore, since no noise-suppressing thermally conductive sheet 30 is provided between each of the high-frequency semiconductor devices 20 and the first thermal dissipation member 41, it is considered that sufficient thermal dissipation cannot be obtained.

In the present disclosure, the term “antenna array for 5G communications” means “an antenna array used in a fifth-generation (5G) mobile communication system”. Also, the term “antenna array” means an aggregation of antennas constituted of at least one antenna.

Therefore, the antenna array 1 for 5G communications according to the embodiment of the present disclosure is preferably used as technology such as Massive MIMO, for example, from the viewpoint of being able to transmit and receive high-frequency radio waves with low power consumption.

Next, each component constituting the antenna array 1 for 5G communications according to the embodiment of the present disclosure will be described.

### Substrate

As illustrated in FIG. 1, the antenna array 1 for 5G communications according to the embodiment of the present disclosure has a substrate 10.

Here, the substrate 10 is a so-called double-sided substrate having circuits on both surfaces (one surface 10a and the other surface 10b). The other detailed conditions of the substrate 10 are not particularly limited, and any known substrate may be selected and used according to required performance.

### High-Frequency Semiconductor Device

As illustrated in FIG. 1, the antenna array 1 for 5G communications according to the embodiment of the present disclosure includes high-frequency semiconductor devices 20 formed on the one surface 10a of the substrate 10.

The high-frequency semiconductor devices are semiconductor devices that process high-frequency (RF) signals. The high-frequency semiconductor devices are not particularly limited as long as the high-frequency semiconductor devices are electronic components made of semiconductors that can process high-frequency signals. For example, the high-frequency semiconductor devices may be integrated circuits such as RFICs or LSIs, CPUs, MPUs, graphic computing elements, or the like.

In the antenna array 1 for 5G communications according to the embodiment of the present disclosure, for example, as illustrated in FIG. 1, a same number of high-frequency semiconductor devices 20 as antennas 50 are provided in the antenna array 1 for 5G communications, in order to activate the antennas 50 described below. However, the number of the high-frequency semiconductor devices 20 and the number of the antennas 50 are not necessarily the same, and depending on design, a single high-frequency semiconductor device 20 may be configured to activate multiple antennas.

In the antenna array 1 for 5G communications according to the embodiment of the present disclosure, a land (not illustrated) may also be provided on the one surface 10a of the substrate 10 all around or partially around the high-frequency semiconductor devices 20.

### Noise-Suppressing Thermally Conductive Sheet

As illustrated in FIG. 1, the antenna array for 5G communications 1 according to the present disclosure includes a noise-suppressing thermally conductive sheet 30 between each of the high-frequency semiconductor devices 20 and a first thermal dissipation member 41 described below.

Since the noise-suppressing thermally conductive sheet 30 can absorb and/or block electromagnetic waves being noise, it is possible to suppress increase in crosstalk without interfering with transmission and reception of radio waves by the antennas, and in addition, it is possible to efficiently transfer heat generated by the high-frequency semiconductor devices 20 to the first thermal dissipation member 41, thus achieving superior thermal dissipation.

Here, the noise-suppressing thermally conductive sheet is, as the name implies, a sheet-like member having electromagnetic noise suppression effect and thermal conductivity. The performance of the noise suppression effect and the thermal conductivity is not particularly limited and may basically be changed as appropriate according to performance required of the antenna array for 5G communications of the present disclosure.

The noise suppression effect of the noise-suppressing thermally conductive sheet may be any as long as noise generated by the high-frequency semiconductor devices 20 and the antennas 50 described below can be suppressed, and for example, the noise-suppressing thermally conductive sheet may have the effect of blocking electromagnetic noise or the effect of absorbing electromagnetic noise.

The size of the noise-suppressing thermally conductive sheet 30 (size along an extending direction of the sheet) is not particularly limited.

For example, as illustrated in FIG. 1, the noise-suppressing thermally conductive sheet 30 may be composed of a plurality of sheets having a size corresponding to the size of the high-frequency semiconductor devices 20. The manner illustrated in FIG. 1 can facilitate pattern design of the substrate 10.

As illustrated in FIG. 2, the size of the noise-suppressing thermally conductive sheet 30 may be increased so that the multiple high-frequency semiconductor devices 20 may be formed for the single noise-suppressing thermally conductive sheet 30. In the case of the manner illustrated in FIG. 2, better noise-suppressing effect and better thermal dissipation may be obtained.

Furthermore, the thickness of the noise-suppressing thermally conductive sheet 30 (thickness along a stacking direction of each component of the antenna array for 5G communications) is not particularly limited, and may be changed as appropriate according to the distance between each of the high-frequency semiconductor devices 20 and the first thermal dissipation member 41, the size of the antenna array 1 for 5G communications, and the like.

For example, from the viewpoint of achieving thermal dissipation and crosstalk suppression effect at higher levels, the thickness of the noise-suppressing thermally conductive sheet 30 is preferably 10 to 3000 μm, and more preferably 200 to 500 μm. If the thickness of the noise-suppressing thermally conductive sheet 30 exceeds 3000 μm, the distance between each of the noise-suppressing thermally conductive sheet 30 and the first thermal dissipation member 41 becomes long, which may result in decrease in thermal conductivity. On the other hand, if the thickness of the noise-suppressing thermally conductive sheet 30 is less than 10 μm, crosstalk suppression effect may be reduced.

The noise-suppressing thermally conductive sheet 30 preferably has a high dielectric constant (relative dielectric constant) in terms of achieving superior crosstalk suppression effect.

Specifically, the dielectric constant of the noise-suppressing thermally conductive sheet 30 is preferably 20 or more, more preferably 25 or more, and even more preferably 30 or more. This is because better crosstalk suppression effect can be obtained by setting the dielectric constant of the noise-suppressing thermally conductive sheet 30 at 20 or more.

A method for adjusting the dielectric constant of the noise-suppressing thermally conductive sheet 30 is not particularly limited, but the dielectric constant may be adjusted as appropriate by changing the type of a binder resin, the material of a thermally conductive filler, the amount of blending, an orientation direction, and the like, as described below.

In addition, the noise-suppressing thermally conductive sheet 30 preferably has a high magnetic permeability (relative magnetic permeability) in terms of achieving superior crosstalk suppression effect.

Specifically, the magnetic permeability of the noise-suppressing thermally conductive sheet 30 preferably exceeds 1, more preferably 2 or more, and even more preferably 5 or more. This is because better crosstalk suppression effect can be obtained by setting the magnetic permeability of the noise-suppressing thermally conductive sheet 30 at more than 1.

A method for adjusting the magnetic permeability of the noise-suppressing thermally conductive sheet 30 is not particularly limited, but the magnetic permeability may be adjusted as appropriate by changing the type of a binder resin, the material of a thermally conductive filler, the amount of blending, an orientation direction, and the like, as described below.

Furthermore, the thermal resistance of the noise-suppressing thermally conductive sheet 30 is preferably 300 Kmm²/W or less, more preferably 35 Kmm²/W or less, and especially preferably 30 Kmm²/W or less. This is because heat generated by the high-frequency semiconductor devices 20 can be transferred to the first thermal dissipation member 41 more efficiently, and thermal dissipation can be further improved. The thermal resistance of the noise-suppressing thermally conductive sheet 30 is preferably 1 Kmm²/W or more, and more preferably 10 Kmm²/W or more. By setting the thermal resistance of the noise-suppressing thermally conductive sheet 30 at 1 Kmm²/W or more, the rate of change in the thermal resistance can be reduced even in the case of changing a contact thermal resistance.

Furthermore, the noise-suppressing thermally conductive sheet 30 preferably has magnetic properties. This is because the noise-suppressing thermally conductive sheet 30 can have electromagnetic wave absorption performance, which provides better crosstalk suppression effect.

A method for adjusting the magnetic properties of the noise-suppressing thermally conductive sheet 30 is not particularly limited, but the magnetic properties may be adjusted by containing magnetic powder or the like in the noise-suppressing thermally conductive sheet 30 and changing the amount of blending and the like.

The noise-suppressing thermally conductive sheet 30 preferably has adhesive or bonding properties on its surfaces. This is because the adhesive or bonding properties can improve adhesiveness between the noise-suppressing thermally conductive sheet 30 and other components (the high-frequency semiconductor device 20 and the first thermal dissipation member 41).

A method for imparting tackiness to surfaces of the noise-suppressing thermally conductive sheet 30 is not particularly limited. For example, a binder resin that makes up the noise-suppressing thermally conductive sheet 30 described below may be optimized to provide tackiness, or adhesive layers with tackiness may be separately provided on the surfaces of the noise-suppressing thermally conductive sheet 30.

Furthermore, the noise-suppressing thermally conductive sheet 30 preferably has flexibility. Since the flexibility allows to easily change the shape of the noise-suppressing thermally conductive sheet 30, the ease of assembling the antenna array 1 for 5G communications is improved, and since the flexibility allows the noise-suppressing thermally conductive sheet 30 to follow the surface shape of the high-frequency semiconductor devices 20, a bonding force with the high-frequency semiconductor devices 20 can also be enhanced. The flexibility of the noise-suppressing thermally conductive sheet 30 is not particularly limited, but for example, a storage elastic modulus at 25° C. measured by dynamic elastic modulus measurement is preferably in the range of 50 kPa to 50 MPa.

A material for making up the noise-suppressing thermally conductive sheet 30 is not particularly limited as long as the material has noise suppression effect and thermal conductivity.

For example, the noise-suppressing thermally conductive sheet 30 may be composed of a material that contains a binder resin, a thermally conductive filler, and other components.

The material that makes up the noise-suppressing thermally conductive sheet 30 will be described below.

### Binder Resin

A binder resin that makes up the noise-suppressing thermally conductive sheet is a resin component that serves as a base material for a noise-suppressing thermally conductive sheet. The type of the binder resin is not particularly limited, and any known type of binder resin may be selected as appropriate. For example, one type of the binder resin is a thermosetting resin.

The thermosetting resin may be, for example, crosslinked rubber, an epoxy resin, a polyimide resin, a bismaleimide resin, a benzocyclobutene resin, a phenol resin, unsaturated polyester, a diallyl phthalate resin, silicone, polyurethane, polyimidosilicone, thermosetting polyphenylene ether, thermosetting polyphenylene ether, thermosetting modified polyphenylene ether, or the like. These may be used alone, or two or more of these may be used in combination.

The crosslinked rubber may be, for example, natural rubber, butadiene rubber, isoprene rubber, nitrile rubber, hydrogenated nitrile rubber, chloroprene rubber, ethylene-propylene rubber, chlorinated polyethylene, chlorosulfonated polyethylene, butyl rubber, halogenated butyl rubber, fluorine rubber, urethane rubber, acrylic rubber, polyisobutylene rubber, silicone rubber, or the like. These may be used alone, or two or more of these may be used in combination.

Among the thermosetting resin described above, silicone is preferably used because of superior molding processability and weatherability, as well as adhesiveness and tracking properties to electronic components. The type of silicone is not particularly limited, and any type of silicone may be selected as appropriate according to the purpose.

From the viewpoint of obtaining the above-described molding processability, weatherability, adhesiveness, and the like, the silicone is preferably silicone containing a liquid silicone gel main agent and a curing agent. Such a silicone may be, for example, an addition-reaction type liquid silicone, a thermal vulcanization type mirable type silicone that uses peroxides for vulcanization, or the like.

As the addition-reaction type liquid silicone, it is preferable to use a two-component addition-reaction type silicone that contains polyorganosiloxane with vinyl groups as a main agent and polyorganosiloxane with Si—H groups as a curing agent, or the like.

In the combination of the main agent of the liquid silicone gel and the curing agent, the ratio between the main agent and the curing agent is preferably 35:65 to 65:35 by mass.

The content of the binder resin in the noise-suppressing thermally conductive sheet is not particularly limited and may be selected as appropriate according to the purpose. For example, from the viewpoint of ensuring the molding processability of the sheet, the adhesiveness of the sheet, and the like, the content of the binder resin is preferably of the order of 20 volume % to 50 volume % of the noise-suppressing thermally conductive sheet, and more preferably 30 volume % to 40 volume %.

### Thermally Conductive Filler

The noise-suppressing thermally conductive sheet 30 may contain a thermally conductive filler in the binder resin. The thermally conductive filler is a component to improve the thermal conductivity of the sheet.

The shape, material, average particle diameter, and the like of the thermally conductive filler are not particularly limited, as long as the thermally conductive filler can improve the thermal conductivity of the sheet.

For example, the shape may be spherical, oval spherical, massive, granular flat, needle-like, fibrous, coiled, or the like. Among these, it is preferable to use a fibrous thermally conductive filler in order to achieve higher thermal conductivity.

The term “fibrous” in the fibrous thermally conductive filler refers to a shape with a high aspect ratio (approximately 6 or more). Therefore, in the present disclosure, the fibrous thermally conductive filler may be, not only a thermally conductive filler of fibrous-shape, rod-shape, or the like, but also a granular filler with a high aspect ratio, a flake-shaped thermally conductive filler, or the like.

The material of the thermally conductive filler is not particularly limited as long as the material has high thermal conductivity, and may be metal such as silver, copper, or aluminum, ceramics such as alumina, aluminum nitride, silicon carbide, or graphite, carbon fiber, or the like.

One type of thermally conductive filler may be used alone, or two or more types of thermally conductive fillers may be used in combination. In the case of using the two or more types of thermally conductive fillers, the thermally conductive fillers may all have the same shape, or the thermally conductive fillers of different shapes may be used in combination.

Among these fibrous thermally conductive fillers, it is preferable to use fibrous metal powder or carbon fiber in terms of obtaining higher thermal conductivity, and it is more preferable to use carbon fiber.

The type of the carbon fiber is not particularly limited, and any type of carbon fiber may be selected as appropriate according to the purpose. For example, pitch-based carbon fiber, PAN-based carbon fiber, graphitized PBO fiber, or carbon fiber synthesized by an arc discharge method, a laser evaporation method, a CVD (chemical vapor deposition) method, a CCVD (catalytic chemical vapor deposition) method, or the like may be used. Among these, carbon fiber made of graphitized PBO fiber or pitch-based carbon fiber is more preferable from the viewpoint of obtaining high thermal conductivity and electrical conductivity.

The carbon fiber may be used after being subject to surface treatment partly or entirely, if necessary. The surface treatment may be, for example, oxidation treatment, nitriding treatment, nitration, sulfonation, or treatment in which metal, a metal compound, an organic compound, or the like is attached or bonded to functional groups introduced to surface by the treatment, or to surface of the carbon fiber. The functional groups may be, for example, hydroxyl groups, carboxyl groups, carbonyl groups, nitro groups, amino groups, or the like.

The average length of a long axis (average long axis length) of the thermally conductive filler is not particular limited and may be selected as appropriate, but from the viewpoint of ensuring high thermal conductivity, the average long axis length is preferably in the range of 50 μm to 300 μm, more preferably in the range of 75 μm to 275 μm, and especially preferably in the range of 90 μm to 250 μm.

Furthermore, an average short axis length of the thermally conductive filler is not specifically limited and may be selected as appropriate. For example, from the viewpoint of ensuring high thermal conductivity, the average short axis length is in the range of 4 μm to 20 μm, and more preferably in the range of 5 μm to 14 μm.

The aspect ratio (average long axis length/average short axis length) of the thermally conductive filler is preferably 6 or more, and more preferably 7 to 30, from the viewpoint of obtaining high thermal conductivity. The aspect ratio should be 6 or more, because the thermal conductivity and other properties are improved even if the aspect ratio is small, but a large property improvement effect cannot be obtained due to reduced orientation and the like. On the other hand, if the aspect ratio exceeds 30, dispersibility in the noise-suppressing thermally conductive sheet is reduced, and thus sufficient thermal conductivity may not be obtained.

The average long axis length and the average short axis length of the thermally conductive filler may be measured by, for example, microscopy, scanning electron microscopy (SEM), or the like, and the average may be calculated from multiple samples.

The content of the thermally conductive filler in the noise-suppressing thermally conductive sheet 30 is not specifically limited and may be selected as appropriate according to the purpose, but the content of the thermally conductive filler is preferably between 4 volume % and 40 volume %, more preferably between 5 volume % and 30 volume %, and especially preferably between 6 volume % and 20 volume %. If the content is less than 4 volume %, it may be difficult to obtain sufficiently low thermal resistance, and if the content exceeds 40 volume %, it may affect the moldability of the noise-suppressing thermally conductive sheet and the orientation of the fibrous thermally conductive filler.

Furthermore, in the noise-suppressing thermally conductive sheet 30, the thermally conductive filler is preferably oriented in one or more directions. This is because by orienting the thermally conductive filler, higher thermal conductivity and electromagnetic wave absorption properties can be achieved.

For example, in a case in which it is desired to increase the thermal conductivity by the noise-suppressing thermally conductive sheet 30 and improve the thermal dissipation of the antenna array for 5G communications according to the present disclosure, the thermally conductive filler may be oriented approximately perpendicularly to a sheet surface. On the other hand, in the cases of changing a current flow in the noise-suppressing thermally conductive sheet to increase noise suppression effect, and the like, the thermally conductive filler may be oriented approximately in parallel to or in another direction to the sheet surface.

Here, the direction that is approximately perpendicular or approximately parallel to the sheet surface means a direction that is almost perpendicular or almost parallel to the direction of the sheet surface. However, since there are some variations in the orientation direction of the thermally conductive filler during manufacturing, a deviation of about ±20° from a direction perpendicular or parallel to an extending direction of the sheet surface described above is acceptable in the present disclosure.

A method for adjusting the orientation angle of the thermally conductive filler is not specifically limited. For example, the orientation angle may be adjusted by making a molded body for the sheet, which is to be the noise-suppressing thermally conductive sheet, and adjusting a cutout angle, while the fibrous thermally conductive filler is oriented.

### Inorganic Filler

In addition to the binder resin and the thermally conductive fiber described above, the noise-suppressing thermally conductive sheet 30 may further contain an inorganic filler. This is because the inorganic filler can further enhance the thermal conductivity of the noise-suppressing thermally conductive sheet and improve the strength of the sheet.

The shape, material, average particle diameter, and the like of the inorganic filler are not specifically limited and may be selected as appropriate according to the purpose. The shape may be, for example, spherical, oval spherical, massive, granular, flat, needle-like, or the like. Among these, the spherical and oval spherical shapes are preferable in terms of fillability, and the spherical shape is especially preferred.

The material of the inorganic filler may be, for example, aluminum nitride (AlN), silica, alumina (aluminum oxide), boron nitride, titania, glass, zinc oxide, silicon carbide, silicon, silicon oxide, metal particles, or the like. These may be used alone as one type, or in combination with two or more types. Among these, alumina, boron nitride, aluminum nitride, zinc oxide, and silica are preferable, and alumina and aluminum nitride are especially preferable in terms of thermal conductivity.

The inorganic filler may be used after being subject to surface treatment. In the case of treating the inorganic filler with a coupling agent as the surface treatment, the dispersibility of the inorganic filler is improved and the flexibility of the noise-suppressing thermally conductive sheet is enhanced.

The average particle diameter of the inorganic filler may be selected as appropriate according to the type of inorganic material and other factors.

In a case in which the inorganic filler is alumina, the average particle diameter thereof is preferably 1 μm to 10 μm more preferably 1 μm to 5 μm, and especially preferably 4 μm to 5 μm. If the average particle diameter is less than 1 μm, viscosity may increase and the inorganic filler may be difficult to mix. On the other hand, if the average particle diameter exceeds 10 μm, the thermal resistance of the noise-suppressing thermally conductive sheet may increase.

Furthermore, in a case in which the inorganic filler is aluminum nitride, the average particle diameter thereof is preferably 0.3 μm to 6.0 μm, more preferably 0.3 μm to 2.0 μm, and especially preferably 0.5 μm to 1.5 μm. If the average particle diameter is less than 0.3 μm, viscosity may increase and the inorganic filler may be difficult to mix, and if the average particle diameter exceeds 6.0 μm, the thermal resistance of the noise-suppressing thermally conductive sheet may increase.

The average particle diameter of the inorganic filler may be measured by, for example, a particle size distribution meter or a scanning electron microscope (SEM).

### Magnetic Metal Powder

Furthermore, it is preferable that the noise-suppressing thermally conductive sheet 30 preferably further contains magnetic metal powder, in addition to the binder resin, fibrous thermally conductive fiber, and inorganic filler described above. By containing the magnetic metal powder, it is possible to enhance the noise absorption performance of the noise-suppressing thermally conductive sheet and further improve the crosstalk suppression effect of the antenna array for 5G communications of the present disclosure.

The type of magnetic metal powder is not particularly limited, as long as the magnetic metal powder can enhance the magnetic properties of the noise-suppressing thermally conductive sheet 30 and improve electromagnetic wave absorption, and any known magnetic metal powder may be selected as appropriate. For example, amorphous metal powder or crystalline metal powder may be used. As the amorphous metal powder, for example, Fe—Si—B—Cr-based, Fe—Si—B-based, Co—Si—B-based, Co—Zr-based, Co—Nb-based, or Co—Ta-based powder or the like is used, and as the crystalline metal powder, for example, pure iron, Fe-based, Co-based, Ni-based, Fe—Ni-based, Fe—Co-based, Fe—Al-based, Fe—Si-based, Fe—Si—Al-based, or Fe—Ni—Si—Al-based powder or the like is used. In addition, as the crystalline metal powder, microcrystalline metal powder that is made finer by adding a trace amount of N (nitrogen), C (carbon), O (oxygen), B (boron), or the like to the crystalline metal powder may be used.

For the magnetic metal powder, a mixture of two or more types of different materials or materials with different average particle diameters may be used.

It is preferable to adjust the shape, such as spherical or flat, of the magnetic metal powder. For example, to increase the fillability, it is preferable to use magnetic metal powder the particles of which have a particle diameter of several micrometers to several tens of micrometers and are spherical. Such magnetic metal powder can be produced, for example, by an atomization method or by a method of pyrolysis of metal carbonyls. The atomization method, which has the advantage of ease in producing spherical powder, is a method of producing powder by pouring molten metal out of a nozzle and spraying a jet stream of air, water, inert gas, or the like on the poured molten metal to solidify the molten metal as droplets. In producing amorphous magnetic metal powder by the atomization method, the cooling rate is preferably set at the order of 1×10⁶ (K/s) to prevent the molten metal from crystallizing.

In the case of producing amorphous alloy powder by the atomization method described above, the surface of the amorphous alloy powder may be made smooth. By using the amorphous alloy powder with less surface irregularity and smaller specific surface area as the magnetic metal powder, fillability can be improved in the binder resin. Furthermore, the fillability can be further improved by coupling treatment.

In addition to the binder resin, thermally conductive filler, inorganic filler, and magnetic metal powder described above, the noise-suppressing thermally conductive sheet may also contain another component as appropriate according to the purpose.

The other component may be, for example, a thixotropy-imparting agent, a dispersing agent, a curing accelerator, a retardant, a fine adhesion-imparting agent, a plasticizer, a flame retardant, an antioxidant, a stabilizer, a colorant, or the like.

### First Thermal Dissipation Member

As illustrated in FIG. 1, the antenna array for 5G communications 1 according to the present disclosure includes a first thermal dissipation member 41 on the one surface 10a of the substrate 10, at a position in contact with the noise-suppressing thermally conductive sheet 30.

Here, the first thermal dissipation member 41 is a member that absorbs heat generated by the heat source (high-frequency semiconductor devices 20) and dissipates the heat to the outside. The first thermal dissipation member 41 is connected to the high-frequency semiconductor devices 20 via the noise-suppressing thermally conductive sheet 30, and therefore diffuses heat generated by the high-frequency semiconductor devices 20 to the outside, thus achieving high thermal dissipation of the antenna array 1 for 5G communications.

The type of the first thermal dissipation member 41 is not particularly limited and may be selected as appropriate according to thermal dissipation required of the antenna array for 5G communications. For example, a radiator, a cooler, a heat sink, a heat spreader, a die pad, a cooling fan, a heat pipe, a metal cover, a chassis, or the like may be used. Among these, it is preferable to use a radiator, cooler, or heat sink in terms of obtaining better thermal dissipation. A material for making the first thermal dissipation member 41 described above may be metal such as aluminum, copper, or stainless steel, graphite, or the like, from the viewpoint of increasing thermal conductivity.

### Antenna

As illustrated in FIG. 1, the antenna array 1 for 5G communications according to the embodiment of the present disclosure includes at least one antenna 50 formed on the other surface 10b of the substrate 10.

Here, the antennas are devices for transmitting and receiving radio waves in a wireless communication environment. In the antenna array 1 for 5G communications according to the embodiment of the present disclosure, antennas used for ordinary antenna arrays may be used, and may be selected as appropriate according to the performance required of the antenna array for 5G communications.

In the antenna array 1 for 5G communications according to the embodiment of the present disclosure, the arrangement pitch P of the antennas 50 is preferably ¼ or more and 1 or less with respect to a communication wavelength, and more preferably ¼ or more and ½ or less. For example, in a case in which a communication wavelength to be used is 28 GHz, the arrangement pitch P of the antennas 50 is preferably 2.5 to 10 mm, and more preferably 2.5 to 5 mm. In a case in which a communication wavelength to be used is 24 Ghz, the arrangement pitch P of the antennas 50 is preferably 18 to 75 mm, and more preferably 18 to 37 mm. This is because of improving the radio wave radiation characteristics of the antenna array.

The number of the antennas 50 in the antenna array 1 for 5G communications according to the embodiment of the present disclosure is not particularly limited as long as the number is at least one, and may be determined as appropriate according to the specifications and required performance of the antenna array for 5G communications. Furthermore, it is preferable that the number of the antennas 50 be multiple (two or more) from the viewpoint of improving the speed of communication and the efficiency of use. For example, in a case in which the antenna array 1 for 5G communications according to the embodiment of the present disclosure adopts Massive MIMO, the number of the antennas 50 may be 128.

### Second Thermal Dissipation Member

As illustrated in FIG. 1, the antenna array 1 for 5G communications according to the embodiment of the present disclosure includes a second thermal dissipation member 42 on the other surface 10b of the substrate 10.

Here, the second thermal dissipation member 42 is a member that absorbs heat generated by the heat source (antennas 50) and dissipates the heat to the outside.

The type of the second thermal dissipation member 42 is not particularly limited, and may be selected as appropriate according to thermal dissipation required of the antenna array for 5G communications according to the present disclosure. For example, as with the first thermal dissipation member 41 described above, a radiator, a cooler, a heat sink, a heat spreader, a die pad, a cooling fan, a heat pipe, a metal cover, a chassis, or the like may be used. Among these, it is preferable to use a heat spreader from the viewpoint of achieving superior thermal dissipation and superior space saving.

As illustrated in FIG. 1, the antennas 50 are provided under the second thermal dissipation member 42, and in a case in which a thermally conductive sheet 60 described below is not disposed between the second thermal dissipation member 42 and each of the antennas 50, it is preferable to leave some space between the second thermal dissipation member 42 and each of the antennas 50 so that the second thermal dissipation member 42 and the antennas 50 do not contact each other. At this time, the distance between the second thermal dissipation member 42 and each of the antennas 50 is not particularly limited, but is preferably about 500 to 2000 μm.

### Thermally Conductive Sheet

As illustrated in FIG. 1, it is further preferable that the antenna array 1 for 5G communications according to the embodiment of the present disclosure includes a thermally conductive sheet 60 between the at least one antenna 50 and the second thermal dissipation member 42. By connecting each of the antennas 50 and the second thermal dissipation member 42 via the thermally conductive sheet 60, heat generated by the antennas 50 can be diffused to the outside to achieve high thermal dissipation of the antenna array 1 for 5G communications.

Here, the thermally conductive sheet 60 is a sheet-like member having thermal conductivity. The performance of the thermal conductivity is not particularly limited, and may basically be changed as appropriate according to performance required of the antenna array for 5G communications of the present disclosure. Unlike the noise-suppressing thermally conductive sheet 30 described above, the thermally conductive sheet 60 does not have a noise-suppressing effect. This is because if the thermally conductive sheet 60 has a noise-suppressing effect, the thermally conductive sheet 60 may degrade the radio wave transmission/reception performance of the antennas 50.

The size of the thermally conductive sheet 60 (size along an extending direction of the sheet (excluding a thickness direction of the sheet)) is not specifically limited. For example, as illustrated in FIG. 1, the thermally conductive sheet 60 may be composed of a plurality of sheets having a size similar to the size of the antennas 50. Also, as illustrated in FIG. 2, the size of the thermally conductive sheet 60 may be increased so that a plurality of antennas 50 are formed for the single thermally conductive sheet 60.

Furthermore, the thickness of the thermally conductive sheet 60 (thickness along a stacking direction of each component of the antenna array for 5G communications) is not particularly limited and may be changed as appropriate according to the distance between each of the antennas 50 and the second thermal dissipation member 42, the size of the antenna array 1 for 5G communications, and the like.

For example, from the viewpoint of achieving thermal dissipation at a higher level, the thickness of the thermally conductive sheet 60 is preferably 500 μm or less, and more preferably 300 μm or less. If the thickness of the thermally conductive sheet 60 exceeds 500 μm, the distance between each of the antennas 50 and the second thermal dissipation member 42 becomes long, which may result in reduction in thermal conductivity.

Furthermore, the thermal resistance of the thermally conductive sheet 60 is preferably 300 Kmm²/W or less, more preferably 35 Kmm²/W or less, and especially preferably 30 Kmm²/W or less. This is because heat generated by the antennas 50 can be transferred to the second thermal dissipation member 42 more efficiently, and the thermal dissipation can be further improved. The thermal resistance of the thermally conductive sheet 60 is preferably 1 Kmm²/W or more, and more preferably 10 Kmm²/W. By setting the thermal resistance of the thermally conductive sheet 60 at 1 Kmm²/W or more, the rate of change in the thermal resistance is reduced even in the case of changing a contact thermal resistance.

The thermally conductive sheet 60 preferably has adhesive or bonding properties on its surfaces. This is because the adhesive or bonding properties can improve the adhesiveness between the thermally conductive sheet 60 and other components (the antennas 50 and the second thermal dissipation member 42).

A method for imparting tackiness to surfaces of the thermally conductive sheet 60 is not particularly limited. For example, a binder resin that makes up the thermally conductive sheet 60 described below may be optimized to provide tackiness, or adhesive layers with tackiness may be separately provided on the surfaces of the thermally conductive sheet 60.

Furthermore, the thermally conductive sheet 60 preferably has flexibility. Since the flexibility allows to easily change the shape of the thermally conductive sheet 60, the ease of assembling the antenna array 1 for 5G communications is improved, and since the flexibility allows the thermally conductive sheet 60 to follow the surface shape of the antenna 50, a bonding force with the antenna 50 can also be enhanced. The flexibility of the thermally conductive sheet 60 is not particularly limited, but for example, a storage elastic modulus at 25° C. measured by dynamic elastic modulus measurement is preferably in the range of 50 kPa to 50 MPa.

A material for making up the thermally conductive sheet 60 is not particularly limited as long as the material has high thermal conductivity. For example, the thermally conductive sheet 60 may be composed of a material that contains a binder resin, a thermally conductive filler, and other components.

The material that makes up the thermally conductive sheet 60 will be described below.

A binder resin that makes up the thermally conductive sheet 60 is a resin component that serves as a base material for a thermally conductive sheet.

The type and content of the binder resin are the same as those of the binder resin in the noise-suppressing thermally conductive sheet 30 described above.

A thermally conductive filler contained in the thermally conductive sheet 60 is a component to improve the thermal conductivity of the sheet. The shape, material, average particle diameter, content, and the like of the thermally conductive filler are the same as those of the thermally conductive filler in the noise-suppressing thermally conductive sheet 30 described above.

In addition to the binder resin and thermally conductive filler, the thermally conductive sheet 60 may also contain other components as appropriate according to the purpose.

The other components may be, for example, an inorganic filler explained in the above description of the noise-suppressing thermally conductive sheet 30, a thixotropy-imparting agent, a dispersing agent, a curing accelerator, a retardant, a fine adhesion-imparting agent, a plasticizer, a flame retardant, an antioxidant, a stabilizer, a colorant, or the like.

Since the thermally conductive sheet 60 is not required to have high noise suppression effect, the thermally conductive sheet 60 should not contain magnetic powder, or even if the thermally conductive sheet 60 contains magnetic powder, the magnetic powder should be in small amount.

### Other Components

The antenna array 1 for 5G communications according to the embodiment of the present disclosure may be provided with other components normally used for antenna arrays as appropriate, in addition to the substrate 10, high-frequency semiconductor devices 20, noise-suppressing thermally conductive sheet 30, first thermal dissipation member 41, second thermal dissipation member 42, antennas 50, and thermally conductive sheet 60 as a suitable component, as described above.

For example, as illustrated in FIG. 1, the antenna array 1 for 5G communications according to the embodiment of the present disclosure may further include a case member 70.

Although not illustrated in the drawing, an adhesive layer or the like may also be formed as needed to bond each component.

### Method for Manufacturing Antenna Array for 5G Communications

A method for manufacturing the antenna array for 5G communications according to the present disclosure is not particularly limited except that the noise-suppressing thermally conductive sheet 30 is formed above or below the at least one high-frequency semiconductor device 20.

For example, as illustrated in FIG. 1, in a case in which the noise-suppressing thermally conductive sheet 30 is composed of a plurality of sheets having a size similar to the size of the high-frequency semiconductor devices 20, the steps of cutting and sizing the noise-suppressing thermally conductive sheet 30 in advance and stacking and crimping the sheets of the noise-suppressing thermally conductive sheet 30 on the individual high-frequency semiconductor devices 20 are included. Also, as illustrated in FIG. 2, in a case in which the noise-suppressing thermally conductive sheet 30 is composed of a single sheet, the steps of stacking and crimping the single sheet of the noise-suppressing thermally conductive sheet 30, after all the high-frequency semiconductor devices 20 are formed on the substrate 10, are included.

The other steps may be carried out according to the conventional manufacturing process of antenna arrays.

In a case in which the thermally conductive sheet 60 is provided between each of the antennas 50 and second thermal dissipation member 42, the steps of stacking and crimping the thermally conductive sheet 60 on the antennas 50, after the antennas 50 are formed, are further included in the same way as the process of forming the noise-suppressing thermally conductive sheet 30.

### Antenna Structure

An antenna structure according to one embodiment of the present disclosure has a substrate; a high-frequency semiconductor device, a noise-suppressing thermally conductive sheet, and a first thermal dissipation member sequentially formed on one surface of the substrate; and an antenna and a second thermal dissipation member sequentially formed on the other surface of the substrate.

In the antenna structure according to the embodiment of the present disclosure, since the noise-suppressing thermally conductive sheet is provided on the one surface of the substrate, it is possible to absorb and/or block an electromagnetic wave being noise, thus suppressing increase in crosstalk without interfering with transmission and reception of a radio wave by the antenna. Furthermore, in the antenna structure according to the embodiment of the present disclosure, since the noise-suppressing thermally conductive sheet is provided between the high-frequency semiconductor device and the first thermal dissipation member, heat generated by the high-frequency semiconductor device can be efficiently transferred to the first thermal dissipation member, thus achieving superior thermal dissipation.

The antenna structure of the present disclosure means a structure with antenna functions, including an antenna device having a single antenna, an antenna array having multiple antennas, and the like.

Components of the antenna structure according to the embodiment of the present disclosure are the same as those of the antenna array for 5G communications according to the embodiment of the present disclosure described above.

### Noise-Suppressing Thermally Conductive Sheet

A noise-suppressing thermally conductive sheet according to an embodiment of the present disclosure is a noise-suppressing thermally conductive sheet used in an antenna array for 5G communications. In the present disclosure, as illustrated in FIG. 1, the noise-suppressing thermally conductive sheet is provided between at least one high-frequency semiconductor device 20 formed on a substrate 10 of an antenna array 1 for 5G communications and a thermal dissipation member (first thermal dissipation member 41 in FIG. 1).

The noise-suppressing thermally conductive sheet 30 according to the embodiment of the present disclosure can absorb and/or block electromagnetic waves being noise, and also have superior thermal conductivity. Therefore, by using the noise-suppressing thermally conductive sheet 30 between the high-frequency semiconductor device 20 and the thermal dissipation member in the antenna array 1 for 5G communications, it is possible to prevent increase in crosstalk and improve thermal dissipation. Therefore, the noise-suppressing thermally conductive sheet 30 according to the embodiment of the present disclosure is suitable for use in the antenna array for 5G communications.

The configuration of the noise-suppressing thermally conductive sheet 30 according to the embodiment of the present disclosure is the same as that of the noise-suppressing thermally conductive sheet described in the antenna array for 5G communications according to the embodiment of the present disclosure described above.

### Thermally Conductive Sheet

A thermally conductive sheet according to one embodiment of the present disclosure is a thermally conductive sheet used in an antenna array for 5G communications.

In the present disclosure, as illustrated in FIG. 1, the thermally conductive sheet is provided between at least one antenna 50 formed on a substrate 10 of an antenna array 1 for 5G communications and a thermal dissipation member (second thermal dissipation member 42 in FIG. 1).

Since the thermally conductive sheet 60 according to the embodiment of the present disclosure has superior thermal conductivity, using the thermally conductive sheet 60 between the antenna 50 and the thermal dissipation member in the antenna array 1 for 5G communications allows to improve thermal dissipation. Therefore, the thermally conductive sheet 60 according to the embodiment of the present disclosure is suitable for use in the antenna array for 5G communications.

The configuration of the thermally conductive sheet 60 according to the embodiment of the present disclosure is the same as that of the thermally conductive sheet described in the antenna array for 5G communications according to the embodiment of the present disclosure described above.

### EXAMPLES

Next, the present disclosure will be concretely described based on examples. However, the present disclosure is not limited to the following examples.

### Example 1

In Example 1, analytical models of the antenna array as illustrated in FIG. 1 were created using a three-dimensional electromagnetic field simulator ANSYS HFSS (Ansys, Inc.), and crosstalk suppression effect and thermal dissipation were evaluated in changing conditions of the noise-suppressing thermally conductive sheet.

(1) For the crosstalk suppression effect of the antenna array, all components except for the noise-suppressing thermally conductive sheet had the same conditions. The conditions for each component included in the antenna array are described below. To simulate the antenna array, models of the antenna array in which only two antenna portions of the antenna array were cut out were created, and repeated boundary conditions were applied. The size of the models of the cutout antenna portions was 10 mm in width, 10 mm in depth, and 5 mm in height.

In the models of the antenna array in which the only two antenna portions were cut out, two microstrip lines were simulated as parallel or aligned, and antennas had a size so as to assume an antenna array with 128 antennas.

For the substrate 10, a substrate material was a FR4 double-sided glass epoxy substrate.

The high-frequency semiconductor devices 20 were simulated by microstrip lines with a width of 55 μm, a thickness of 20 μm, and a length of 2000 μm. In each sample, output power of the high-frequency semiconductor devices 20 was 5 W.

For the first thermal dissipation member 41, a heat sink constituted of an aluminum plate of the same size (20 mm in width and 10 mm in depth) as the model of the antenna array was used.

For the antennas 50, patch antennas having a resonant frequency of 28 GHz were used.

For the thermally conductive sheet 60, two-component addition-reaction type liquid silicone was used as a resin binder, and 15 mass % pitch-based carbon fiber with an average fiber length of 150 μm was used as a fibrous thermally conductive filler. The thermally conductive sheet 60 had a size of 5 mm in width, 5 mm in depth, and 0.5 mm in thickness, and a thermal resistance of 40 Kmm²/W.

For the second thermal dissipation member 42, a thermal spreader made of aluminum nitride of the same size as the model of the antenna array was used.

For the case member 70, a resin case was used.

(2) The configuration of the noise-suppressing thermally conductive sheet used in each analytical model of the antenna array is as follows.

Comparative Example 1-1: Air was used as the noise-suppressing thermally conductive sheet. In other words, a 500 μm gap was provided between each high-frequency semiconductor device 20 and the first thermal dissipation member 41 without using the noise-suppressing thermally conductive sheet 30.
Comparative Example 1-2: An insulating sheet containing 85 mass % of magnetic powder was used as the noise-suppressing thermally conductive sheet 30. The thickness of the sheet was 500 μm and the thermal resistance thereof was 300 Kmm²/W.
Comparative Example 1-3: A sheet made of a dielectric material (a relative permittivity of 4) was used as the noise-suppressing thermally conductive sheet 30. The thickness of the sheet was 500 μm and the thermal resistance thereof was 200 Kmm²/W.
Inventive Example 1-1: A sheet containing 6 mass % of a fibrous thermally conductive filler (pitch-based carbon fiber with an average fiber length of 200 μm) and 85 mass % of magnetic powder was used as the noise-suppressing thermally conductive sheet 30. The thickness of the sheet was 500 μm and the thermal resistance thereof was 40 Kmm²/W.

### Evaluation of Crosstalk Suppression Effect

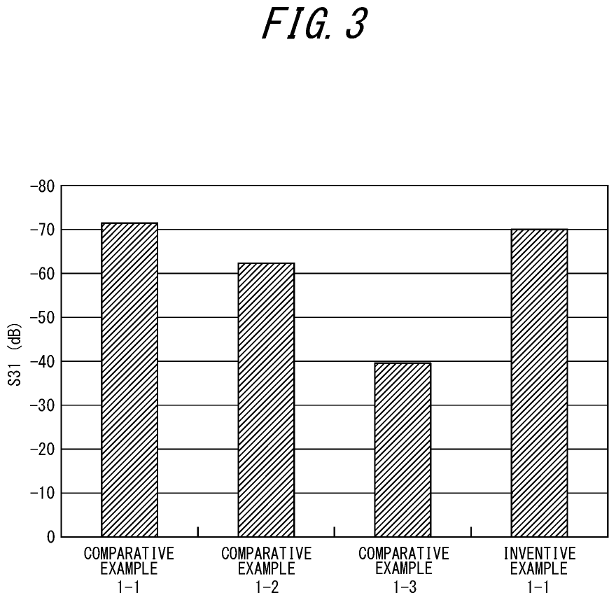

An evaluation of crosstalk suppression effect of each analytical model of the antenna array was performed by measuring transmission characteristics between two microstrip lines. Terminals at both ends of the microstrip line that was assumed to be one high-frequency semiconductor device were designated as a port 1 and a port 2, respectively, along a longitudinal direction of the model, and terminals at both ends of the other microstrip line were similarly designated as port 3 and port 4, to calculate the amount of near-end crosstalk (S31) expected in each analytical model. FIG. 3 illustrates the calculated S31.

From the results illustrated in FIG. 3, superior crosstalk suppression effect was confirmed in the analysis model of Inventive Example 1-1, which was included in the scope of the disclosure, and in the analysis model of Comparative Example 1-1, which used no noise-suppressing thermally conductive sheet 30.

### Evaluation of Thermal Dissipation

Thermal dissipation of each analytical model of the antenna array was evaluated by calculating a predicted surface temperature of the high-frequency semiconductor device 20 after a steady state under a temperature of 25° C. Table 1 provides the calculated surface temperatures.

| | | | | Inventive |
|---|---|---|---|---|
| | Comparative | Comparative | Comparative | Example |
| | Example 1-1 | Example 1-2 | Example 1-3 | 1-1 |
| Surface | 99.9 | 69.6 | 65.9 | 57.7 |
| temperature | | | | |
| of high-frequency | | | | |
| semiconductor | | | | |
| device (° C.) | | | | |

From the results in Table 1, it was found that the analysis model of Inventive Example 1-1, which was included in the scope of the present disclosure, had the best thermal dissipation. On the other hand, for the analysis model of Comparative Example 1-1, which used no noise-suppressing thermally conductive sheet 30, it was found that the surface temperature of the high-frequency semiconductor device 20 was high, and thermal dissipation was not achieved.

### Example 2

In Example 2, under the same conditions as in Example 1, analytical models of the antenna array as illustrated in FIG. 1 were created using the 3D electromagnetic field simulator to evaluate crosstalk suppression effect in the case of changing the dielectric constant of the noise-suppressing thermally conductive sheet.

(1) For each analytical model of the antenna array, all conditions were the same except for the conditions of the noise-suppressing thermally conductive sheet, and the conditions are as described in Example 1.

(2) The dielectric constant and magnetic permeability of the noise-suppressing thermally conductive sheet used for each analytical model of the antenna array are as follows. Samples 1 and 2 had the same conditions except for the condition of the dielectric constant of the noise-suppressing thermally conductive sheet.

Sample 2-1: A sheet having a dielectric constant of 10 and a magnetic permeability of 5 was used as the noise-suppressing thermally conductive sheet 30.
Sample 2-2: A sheet having a dielectric constant of 20 and a magnetic permeability of 5 was used as the noise-suppressing thermally conductive sheet 30.

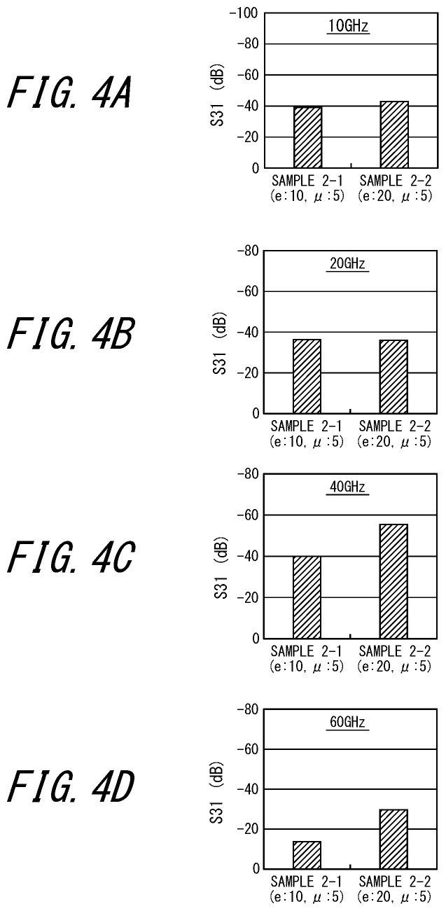

The crosstalk suppression effect was evaluated by calculating the expected amount of near-end crosstalk (S31) in each analysis model at 10 GHz, 20 GHz, 40 GHz, and 60 GHz using electromagnetic field analysis software (ANSYS, HFSS). FIGS. 4A to 4D illustrate S31 calculated at 10 GHz, 20 GHz, 40 GHz, and 60 GHz, respectively.

From the results of FIGS. 4A to 4D, it was found that in any frequency bands, Sample 2-2 having a dielectric constant of 20 of the noise-suppressing thermally conductive sheet 30 had higher crosstalk suppression effect.

### Example 3

In Example 3, under the same conditions as in Example 1, analytical models of the antenna array as illustrated in FIG. 1 were created using the three-dimensional electromagnetic field simulator, and crosstalk suppression effect in the case of changing the dielectric constant of the noise-suppressing thermally conductive sheet was evaluated.

(1) For each analytical model of the antenna array, all conditions were the same except for the conditions of the noise-suppressing thermally conductive sheet, and each condition is as described in Example 1.

(2) The dielectric constant and magnetic permeability of the noise-suppressing thermally conductive sheet used for each analytical model of the antenna array are as follows. Samples 1 and 2 had the same conditions except for the condition of the dielectric constant of the noise-suppressing thermally conductive sheet.

Sample 3-1: A sheet having a dielectric constant of 10 and a magnetic permeability of 5 was used as the noise-suppressing thermally conductive sheet 30.
Sample 3-2: A sheet having a dielectric constant of 10 and a magnetic permeability of 1 was used as the noise-suppressing thermally conductive sheet 30.

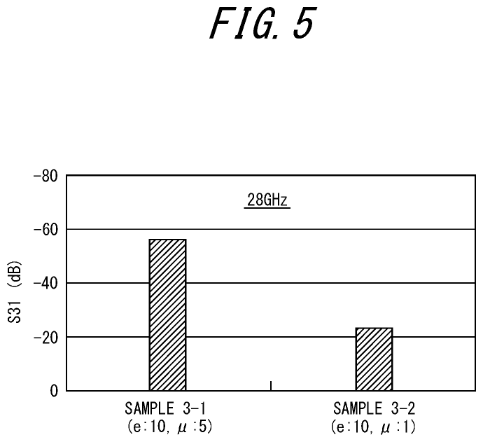

For the evaluation of the crosstalk suppression effect, the amount of near-end crosstalk (S31) expected in each analysis model at 28 GHz was calculated by electromagnetic field analysis software (ANSYS, HFSS). FIG. 5 illustrates the calculated S31.

From the results in FIG. 5, it was found that Sample 3-1, which had a higher magnetic permeability of the noise-suppressing thermally conductive sheet 30, had higher crosstalk suppression effect.

### INDUSTRIAL APPLICABILITY

According to the present disclosure, it is possible to provide an antenna array for 5G communications and an antenna structure having superior thermal dissipation and crosstalk suppression effect. The present disclosure also makes it possible to provide a noise-suppressing thermally conductive sheet and a thermally conductive sheet suitable for use in the antenna array for 5G communications and the antenna structure having superior thermal dissipation and crosstalk suppression effect.

### REFERENCE SIGNS LIST

1 antenna array for 5G communications

10 substrate

10a one surface of substrate

10b the other surface of substrate

20 high-frequency semiconductor device

30 noise-suppressing thermally conductive sheet

41 first thermal dissipation member

42 second thermal dissipation member

50 antenna

60 thermally conductive sheet

70 case member

P arrangement pitch of antennas

1. An antenna array for 5G communications comprising:
a substrate;
at least one high-frequency semiconductor device, a noise-suppressing thermally conductive sheet, and a first thermal dissipation member sequentially formed on one surface of the substrate; and
at least one antenna and a second thermal dissipation member sequentially formed on the other surface of the substrate.

2. The antenna array for 5G communications according to claim 1, further comprising a thermally conductive sheet disposed between the at least one antenna and the second thermal dissipation member.

3. The antenna array for 5G communications according to claim 1, wherein the noise-suppressing thermally conductive sheet contains magnetic powder.

4. The antenna array for 5G communications according to claim 1, wherein the noise-suppressing thermally conductive sheet contains carbon fiber.

5. The antenna array for 5G communications according to claim 1, wherein the noise-suppressing thermally conductive sheet has a dielectric constant of 20 or more.

6. The antenna array for 5G communications according to claim 1, wherein the noise-suppressing thermally conductive sheet has a magnetic permeability of more than 1.

7. The antenna array for 5G communications according to claim 1, wherein the noise-suppressing thermally conductive sheet has a thermal resistance of 300 Kmm²/W or less.

8. The antenna array for 5G communications according to claim 1, wherein the antenna array for 5G communications is used as Massive MIMO.

9. An antenna structure comprising:
a substrate;
a high-frequency semiconductor device, a noise-suppressing thermally conductive sheet, and a first thermal dissipation member sequentially formed on one surface of the substrate; and
an antenna and a second thermal dissipation member sequentially formed on the other surface of the substrate.

10. A noise-suppressing thermally conductive sheet used in an antenna array for 5G communications, wherein the noise-suppressing thermally conductive sheet is disposed between at least one high-frequency semiconductor device formed on a substrate and a thermal dissipation member.

11. A thermally conductive sheet used in an antenna array for 5G communications, wherein the thermally conductive sheet is disposed between at least one antenna formed on a substrate and a thermal dissipation member.
